(19) United States
(12) Patent Application Publication
(10) Pub. No.: US 2008/0153320 A1
(43) Pub. Date: Jun. 26, 2008

(54) Space-saving IC card and card slot arrangement

(76) Inventor: Yi-Wen Lin, Wuku Hsiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/641,799

(22) Filed: Dec. 20, 2006

(51) Int. Cl. H05K 1/14

(52) U.S. Cl. 439/68

(57) ABSTRACT

A space-saving IC card and card slot arrangement in which the IC card has a flat substrate with a rectangular front protrusion forwardly extending from a part of the front side thereof for insertion into a card slot in a mobile electronic device, and an IC chip installed in the rectangular front protrusion and having stored therein a data.

### BACKGROUND OF THE INVENTION

1. Field of the Invention:

The present invention relates to a space-saving IC card and card slot arrangement, which greatly reduces the size of the card slot of a mobile electronic device, for example, a mobile phone.

2. Description of the Related Art:

A mobile electronic device may provide two input modes. One input mode allows the user to input data through the buttons of the mobile electronic device. The other input mode allows the user to input data through the display screen of the mobile electronic device by writing. These two input modes take much time to input data.

Nowadays, mobile electronic devices with a card slot for reading data from an IC card have been developed and have appeared on the market. As illustrated in FIGS. 1 and 2, the mobile electronic device, i.e., mobile phone 5 has a card slot 51 defined in its one side and a card reader 52 installed in the card slot 51. An IC card 4 insertable into the card slot 51 is shown having an IC chip 41 that has stored therein a data. When inserted the IC card 4 into the card slot 51, the card reader 52 reads in data from the IC chip 41. This design allows quick input of data into the mobile phone 5. However, the card slot 51 occupies much installation space of the mobile phone 5.

### SUMMARY OF THE INVENTION

The present invention has been accomplished under the circumstances in view. It is the main object of the present invention to provide a space-saving IC card and card slot arrangement, which greatly reduces the size of the card slot of a mobile electronic device, for example, a mobile phone. To achieve this and other objects of the present invention, the space-saving IC card and IC card slot arrangement comprises an IC card, and a card slot defined in a mobile electronic device for receiving the IC card. The IC card has a flat substrate with a rectangular front protrusion forwardly extending from a part of the front side thereof for insertion into the card slot in the mobile electronic device, and an IC chip installed in the rectangular front protrusion and having stored therein a data. The card slot of the mobile electronic device fits the rectangular front protrusion in size, and is adapted to receive the rectangular front protrusion and to read data from the IC chip and to stop the flat substrate outside the mobile electronic device.

In an alternate form of the present invent invention, the IC card is made in the form of a business card, which comprises a flat substrate that has a rectangular front protrusion protruded from a part of the front side thereof, an IC chip installed in the rectangular front protrusion of the flat substrate, and a supplementary substrate hinged to the front side of said flat substrate by a hinge. The supplementary substrate has a notch on the side that is hinged to the flat substrate for receiving the rectangular front protrusion of the substrate. The supplementary substrate can be turned relative to the flat substrate between an extended position where the flat substrate and the supplementary substrate are kept in flush on a plane to constitute the business card and the rectangular front protrusion of the flat substrate is received in the notch of the supplementary substrate, and a received position where the supplementary substrate and the flat substrate are arranged in a stack.

### BRIEF DESCRIPTION OF THE DRAWINGS

FIG. 1 illustrates the relationship between a mobile phone and an IC card according to the prior art.

FIG. 2 is an exploded view of FIG. 2.

FIG. 3 is an exploded view of the present invention.

FIG. 4 is a perspective assembly view of the present invention.

FIG. 5 is a front view of an alternate form of the IC card according to the present invention.

FIG. 5-1 corresponding to FIG. 5, showing the supplementary substrate turned toward the back side of the flat substrate.

FIG. 5-2 corresponds to FIG. 5-1, showing the flat substrate and the supplementary substrate arranged in a stack.

FIG. 6 is an elevational view of still another alternate form of the IC card according to the present invention.

### DETAILED DESCRIPTION OF THE PREFERRED EMBODIMENT

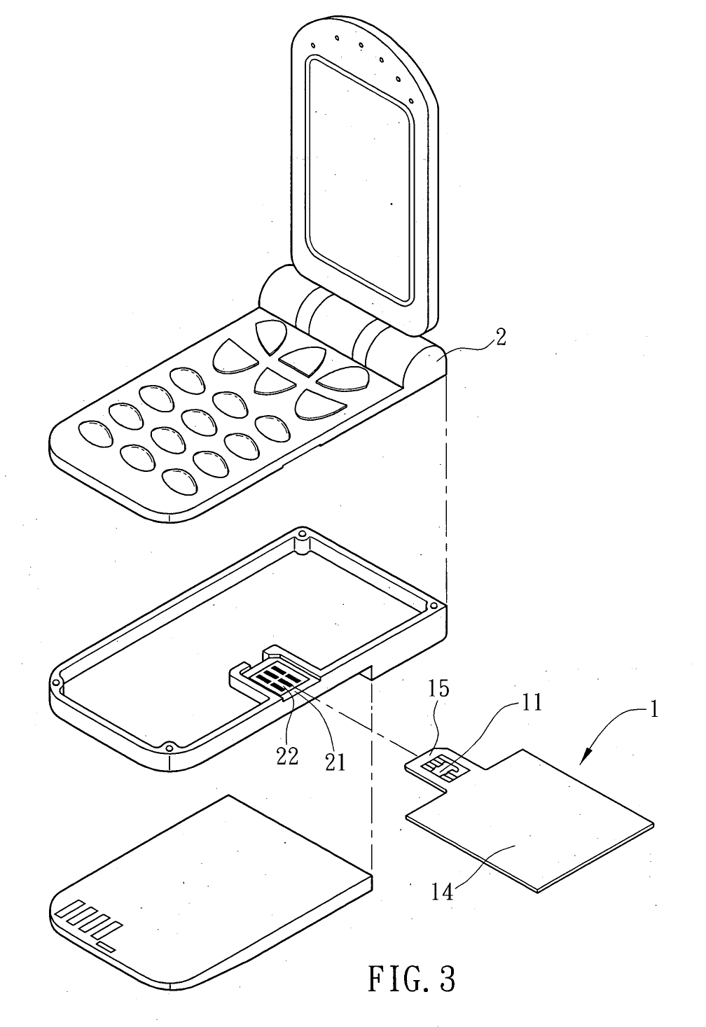

Referring to FIG. 3, a card slot 21 is defined in a mobile telephone 2 at one lateral side for receiving an IC card 1. A card reader 22 is installed in the card slot 21 and adapted to read storage data from the IC card 1 that is inserted into the card slot 21. The IC card 1 can be, for example, a memory card having a flat substrate 14 and an IC chip 11 installed in the flat substrate 14. The flat substrate 14 has a rectangular front protrusion 15 projecting from the front side thereof. The IC chip 11 is installed in the rectangular front protrusion 15, having stored therein a data. According to this embodiment, the rectangular front protrusion 15 projects from the middle part of the front side of the flat substrate 14, and fits the card slot 21, i.e., the card slot 21 has a width approximately equal to the width of the rectangular front protrusion 15 and smaller than the width of the flat substrate 14.

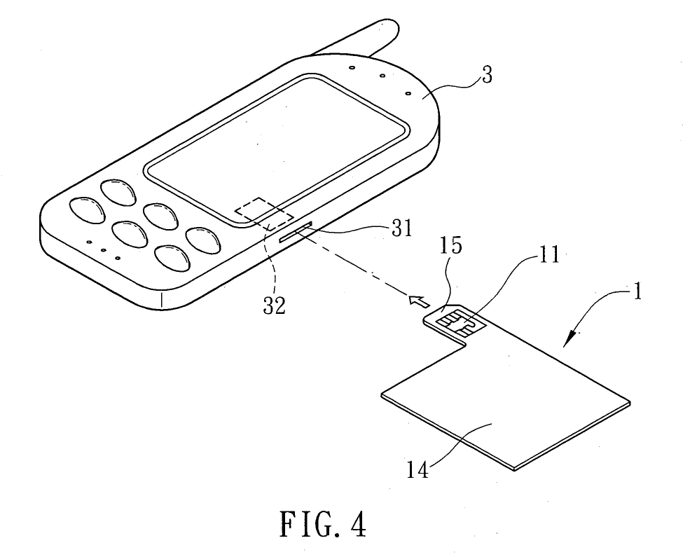

FIG. 4 shows an alternate form of the IC card 1 according to the present invention. This alternate form is substantially similar to the embodiment shown in FIG. 3 with the exception that the rectangular front protrusion 15 of the IC card 1 projects from the front side of the flat substrate 14 in flush with one lateral side of the flat substrate 14. The rectangular front protrusion 15 of the IC card 1 fits the card slot 31 of a mobile telephone 3, which has a card reader 32 in the card slot 31 for reading storage data from the IC chip 11 in the IC card 1.

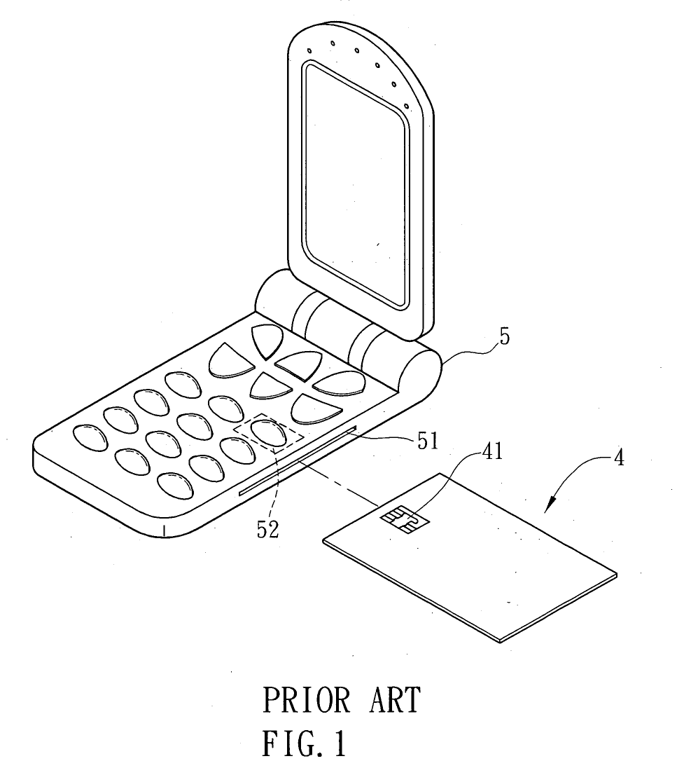

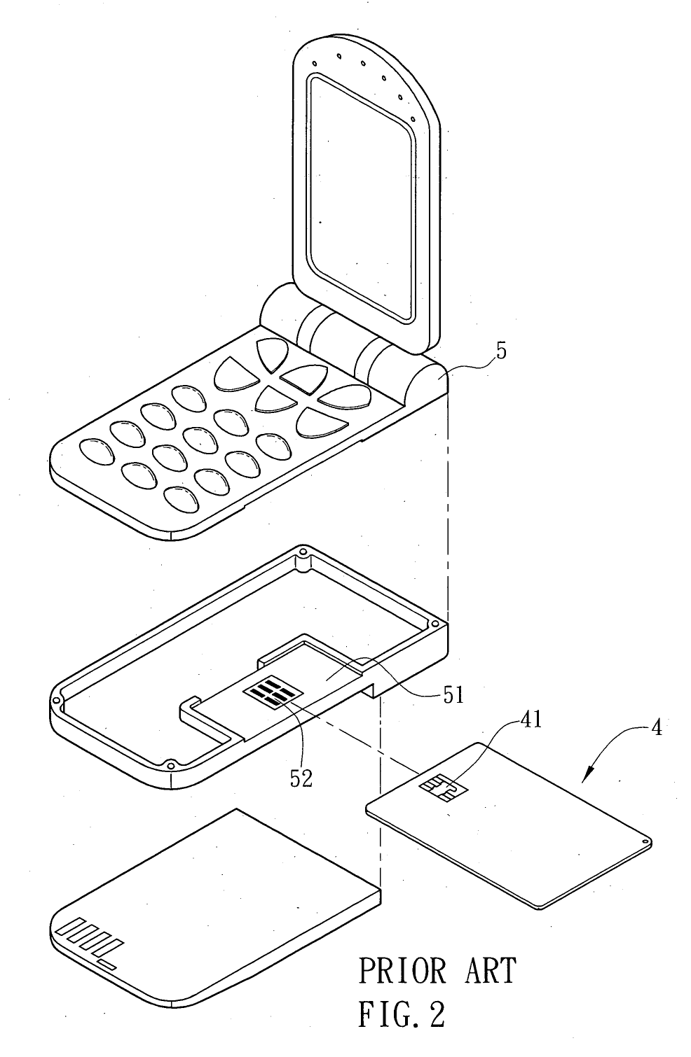

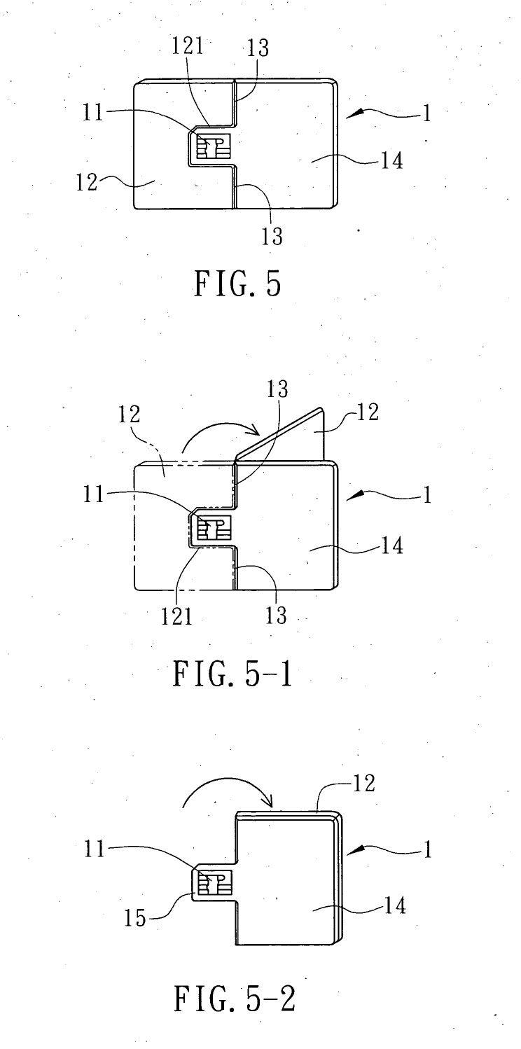

FIGS. 5, 5-1 and 5-2 show another alternate form of the IC card 1 according to the present invention. The IC card 1 is made in the form of a business card that has a flat substrate 14, which has a rectangular front protrusion 15 protruded from a part of the front side, an IC chip 11 installed in the rectangular front protrusion 15 of the flat substrate 14, and a supplementary substrate 12 hinged to the front side of the flat substrate 14 by a hinge 13. The supplementary substrate 12 has a width and length equal to the flat substrate 14 and a notch 121 on the side that is hinged to the flat substrate 14 for receiving the rectangular front protrusion 15 of the flat substrate 14. The supplementary substrate 12 can be turned relative to the flat substrate 14 between an extended position where the flat substrate 14 and the supplementary substrate 12 are kept in flush on a plane and the rectangular front protrusion 15 of the flat substrate 14 is received in the notch 121 of the supplementary substrate 12 (see FIG. 5), and a received position where the supplementary substrate 12 and the flat substrate 14 are arranged in a stack (see FIG. 5-2).

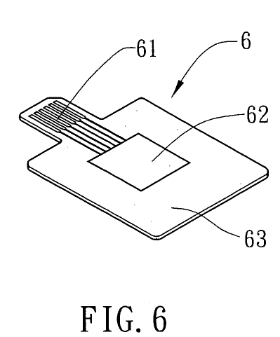

FIG. 6 shows another alternate form of the IC card. According to this embodiment, the IC card, referenced by 6, has a memory 62 installed in the flat substrate 63 thereof, and gold fingers 61 electrically extending from the memory 62 to the rectangular front protrusion of the flat substrate 63.

Although particular embodiments of the invention have been described in detail for purposes of illustration, various modifications and enhancements may be made without departing from the spirit and scope of the invention.

What the invention claimed is:

1. A space-saving IC card and card slot arrangement comprising an IC card and a card slot defined in a mobile electronic device for receiving said IC card and reading data from said IC card, wherein said IC card comprises a flat substrate, said flat substrate having a rectangular front protrusion forwardly extending from a part of a front side thereof for insertion into said card slot, and an IC chip installed in said rectangular front protrusion and having stored therein a data.

2. The space-saving IC card and card slot arrangement as claimed in claim 1, wherein said card slot fits said rectangular front protrusion in size and is adapted to receive said rectangular front protrusion and to read data from said IC chip and to stop said flat substrate outside said mobile electronic device.

3. The space-saving IC card and card slot arrangement as claimed in claim 1, wherein said rectangular front protrusion forwardly extends forwardly from a middle part of the front side of said flat substrate.

4. The space-saving IC card and card slot arrangement as claimed in claim 1, wherein said rectangular front protrusion forwardly extends forwardly from a part of the front side of said flat substrate in flush with one lateral side of said flat substrate.

5. The space-saving IC card and card slot arrangement as claimed in claim 1, wherein said. IC card further comprising a supplementary substrate hinged to the front side of said flat substrate by a hinge, said supplementary substrate having a width and length equal to said flat base and a notch on one side thereof that is hinged to the front side of said flat substrate for receiving said rectangular front protrusion of said flat substrate.

6. A space-saving IC card and card slot arrangement comprising an IC card and a card slot defined in a mobile electronic device for receiving said IC card and reading data from said IC card, wherein said IC card comprises a flat substrate, said flat substrate having a rectangular front protrusion forwardly extending from a part of a front side thereof for insertion into said card slot, a memory installed in said flat substrate, and a row of golf fingers extending from said memory to said rectangular front protrusion; said card slot fits said rectangular front protrusion in size and is adapted to receive said rectangular front protrusion and to read data from said memory through said golf fingers and to stop said flat substrate outside said mobile electronic device.
